(19) United States
(12) Patent Application Publication
(10) Pub. No.: US 2013/0294766 A1
(43) Pub. Date: Nov. 7, 2013

(54) Dark Current Cancellation For Optical Power Monitoring In Optical Transceivers

(71) Applicant: SIFOTONICS TECHNOLOGIES CO., LTD., Woburn, MA (US)

(72) Inventors: Pengfei Cai, Beijing (CN); Mengyuan Huang, Beijing (CN); Tielong Xu, Tianjin (CN); Dong Pan, Andover, MA (US)

(73) Assignee: SiFotonics Technologies Co., Ltd., Woburn, MA (US)

(21) Appl. No.: 13/887,106

(22) Filed: May 3, 2013

Related U.S. Application Data
(60) Provisional application No. 61/688,057, filed on May 5, 2012.
(60) Provisional application No. 61/688,058, filed on May 5, 2012.
(60) Provisional application No. 61/688,060, filed on May 5, 2012.

(51) Int. Cl. H04B 10/079; H01L 31/18

(52) U.S. Cl. CPC H04B 10/07953; H01L 31/18
USPC 398/26; 438/69

(57) ABSTRACT

Various embodiments of a method and device for dark current cancellation for optical power monitoring in optical transceivers are presented. In one aspect, a device includes a photosensitive module and a processing module coupled to the photosensitive module. The photosensitive module is configured to detect an optical signal and generate a first signal responsive to detecting the optical signal. The processing module is configured to determine a value of a second signal that is related to noise and determine a value of a third signal that is related to a difference between a value of the first signal and the value of the second signal.

### CROSS-REFERENCE TO RELATED PATENT APPLICATIONS

This application is the non-provisional application or, and claims the priority benefit of U.S. Patent Application Nos. 61/688,057, 61/688,058 and 61/688,060, all filed on May 5, 2012, which are herein incorporated by reference in their entirety.

### BACKGROUND

1. Technical Field

The present disclosure relates to optical communications. More particularly, the present disclosure relates to dark current cancellation for optical power monitoring in optical transceivers.

2. Description of Related Art

In general, an optical transceiver includes a transmitter portion and a receiver portion. It can be used for converting an optical signal into an electrical signal as well as converting an electrical signal into an optical signal. The receiver portion receives an optical signal from an optical fiber and converts the optical signal into a corresponding electrical signal, for example, by using a photodiode and a pre-amplifier that amplifies the electrical signal to a suitable amplitude. The receiver portion then outputs the amplified electrical signal to a host board. The transmitter portion receives an electrical signal from the host board, and converts the electrical signal into a corresponding optical signal, for example, by using a driver and a laser or optical modulator. The transmitter portion then sends the optical signal into an optical fiber.

During transceiver operation, it is necessary to monitor optical power received by one or more photodetectors of the transceiver for network administration and/or for adaptively adjusting the optical output power at the transmitter portion. However, dark current of the photodetector(s) can reduce the accuracy of optical power monitoring, especially when dark current is large or is close to photocurrent typically during high temperature operations. This problem limits the development of long-haul high-speed optical communication systems.

Additionally, an avalanche photodiode (APD) is a kind of temperature sensitive device because its most critical parameters (i.e., dark current and ionization coefficients) are dependent on the ambient temperature. When an avalanche photodiode operates in a large temperature range, its dark current and gain tend to have a large variation at the lowest and the highest temperatures. Additionally, high dark current at high temperature tends to hamper the accuracy of optical power monitoring, especially when dark current is close to photocurrent. This problem generally becomes worse for an APD with high dark current (e.g., GeSi APD or III-V/Si APD).

### SUMMARY

In one aspect, a device may include a photosensitive module and a processing module coupled to the photosensitive module. The photosensitive module may be configured to detect an optical signal and generate a first signal responsive to detecting the optical signal. The processing module may be configured to determine a value of a second signal that is related to noise and determine a value of a third signal that is related to a difference between a value of the first signal and the value of the second signal.

In one embodiment, the photosensitive module may include at least a main photodetector.

In one embodiment, the first signal may be a total current, the second signal may be a reference dark current, and the third signal may be a signal current.

In one embodiment, the main photodetector may be a photodiode or an APD.

In one embodiment, the photosensitive module may further include a trans-impedance amplifier (TIA) coupled to the main photodetector.

In one embodiment, the processing module may include a temperature sensor and a control unit. The temperature sensor may be configured to detect an ambient temperature around the photosensitive module and generate a temperature signal responsive to detecting the ambient temperature. The control unit may be coupled to receive the temperature signal and the first signal. The control unit may be configured to determine the value of the third signal based at least in part on the temperature signal.

In one embodiment, the control unit may determine the value of the third signal by: determining the value of the second signal corresponding to a temperature associated with the temperature signal using a lookup table; and subtracting the value of the second signal from the value of the first signal.

In one embodiment, the control unit may determine the value of the third signal by: calculating the value of the second signal corresponding to a temperature associated with the temperature signal using temperature coefficients associated with the photosensitive module; and subtracting the value of the second signal from the value of the first signal.

In one embodiment, the photosensitive module may further include a heating element that is configured to generate heat when switched on by the control unit responsive to the ambient temperature being less than a threshold temperature.

In one embodiment, the photosensitive module may further include a dummy photodetector that is configured to detect the noise and generate the second signal responsive to detecting the noise.

In one embodiment, the dummy photodetector may be a discrete photodetector separate from the main photodetector, and one or more physical characteristics of the dummy photodetector may be substantially identical to corresponding one or more physical characteristics of the main photodetector.

In one embodiment, the dummy photodetector and the main photodetector may be integral parts of an integrated circuit (IC) chip.

In one embodiment, the main photodetector may be an avalanche photodiode. The IC chip may include: a substrate; an electrically insulating layer on the substrate; a first semiconductor structure on the electrically insulating layer as the main photodetector; a second semiconductor structure on the electrically insulating layer as the dummy photodetector; a passivation layer on the electrically insulating layer such that the main photodetector and the dummy photodetector are physically and electrically isolated from one another by the passivation layer at least in a direction substantially parallel to a surface of the electrically insulating layer; and an optical barricade layer at least partially surrounding the dummy photodetector such that an optical coupling region of the dummy photodetector is covered by the optical barricade layer to avoid the dummy photodetector receiving the optical signal.

In one embodiment, the electrically insulating layer may be a buried oxide (BOX) layer, the substrate may be a silicon substrate, and the silicon substrate and the BOX layer may be at least a part of a silicon-on-insulator wafer.

In one embodiment, the optical barricade layer may include a metallic material.

In one embodiment, the photosensitive module may further include a TIA coupled to the main photodetector.

In one embodiment, the processing module may include: a first current mirror coupled to receive the first signal from the main photodetector, the first current mirror configured to mirror the first signal; a second current mirror coupled to receive the second signal from the dummy photodetector, the second current mirror configured to mirror the second signal; and a control unit coupled to receive the mirrored first signal and the mirrored second signal from the first and the second current mirrors. The control unit may be configured to determine the value of the third signal by subtracting the value of the second signal from the value of the first signal.

In one embodiment, the photosensitive module may include: a main photodetector, the main photodetector configured to detect the optical signal and generate a total current as the first signal responsive to detecting the optical signal; and a dummy photodetector, the dummy photodetector configured to detect the noise and generate a reference dark current as the second signal responsive to detecting the noise.

In one embodiment, the dummy photodetector may be a discrete photodetector separate from the main photodetector, and one or more physical characteristics of the dummy photodetector may be substantially identical to corresponding one or more physical characteristics of the main photodetector.

In one embodiment, the dummy photodetector and the main photodetector may be integral parts of an IC chip.

In one embodiment, the main photodetector may be an avalanche photodiode. The IC chip may include: a substrate; an electrically insulating layer on the substrate; a first semiconductor structure on the electrically insulating layer as the main photodetector; a second semiconductor structure on the electrically insulating layer as the dummy photodetector; a passivation layer on the electrically insulating layer such that the main photodetector and the dummy photodetector are physically and electrically isolated from one another by the passivation layer at least in a direction substantially parallel to a surface of the electrically insulating layer; and an optical barricade layer at least partially surrounding the dummy photodetector such that an optical coupling region of the dummy photodetector is covered by the optical barricade layer to avoid the dummy photodetector receiving the optical signal.

In one embodiment, the electrically insulating layer may be a BOX layer, the substrate may be a silicon substrate, and the silicon substrate and the BOX layer may be at least a part of a silicon-on-insulator wafer.

In one embodiment, the optical barricade layer may include a metallic material.

In one embodiment, the photosensitive module may include a ROSA, and the photosensitive module may further include a TIA coupled to the main photodetector.

In one embodiment, the processing module may include: a first current mirror coupled to receive the first signal from the main photodetector, the first current mirror configured to mirror the first signal; a second current mirror coupled to receive the second signal from the dummy photodetector, the second current mirror configured to mirror the second signal; and a control unit coupled to receive the mirrored first signal and the mirrored second signal from the first and the second current mirrors. The control unit may be configured to determine the value of the third signal by subtracting the value of the second signal from the value of the first signal.

In another aspect, a method of manufacturing a photosensitive IC chip may include: forming a silicon-on-insulator (SOI) structure including an electrically insulating layer on a substrate; performing an etching process to etch the SOI structure to remove layers of the SOI structure above the electrically insulating layer; forming a first semiconductor structure on the electrically insulating layer as a main photodetector; forming a second semiconductor structure on the electrically insulating layer as a dummy photodetector (the first and second semiconductor structures can be formed simultaneously); depositing a passivation layer over the first semiconductor structure, the second semiconductor structure, and the electrically insulating layer such that the first semiconductor structure and the second semiconductor structure are physically and electrically isolated from one another by the passivation layer at least in a direction substantially parallel to a surface of the electrically insulating layer; and performing a planarization process to planarize at least the passivation layer.

In one embodiment, the electrically insulating layer may be a BOX layer, and the substrate may be a silicon substrate.

In one embodiment, the optical barricade layer may include a metallic material.

In one embodiment, the method may further include forming an optical barricade layer that at least partially surrounds the second semiconductor structure such that an optical coupling region of the second semiconductor structure is covered by the optical barricade layer to avoid the second semiconductor structure receiving the optical signal.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure. The drawings may not necessarily be in scale so as to better present certain features of the illustrated subject matter.

FIG. 1 is a block diagram of a device for dark current cancellation for an optical transceiver in accordance with an embodiment of the present disclosure.

FIG. 2 is a block diagram of a device for dark current cancellation for an optical transceiver in accordance with another embodiment of the present disclosure.

FIG. 3 is a block diagram of a device for dark current cancellation for an optical transceiver in accordance with yet another embodiment of the present disclosure.

FIG. 4 is a top view of a 6-pin ROSA for dark current cancellation for an optical transceiver in accordance with an embodiment of the present disclosure.

FIG. 5 is a top view of a 6-pin ROSA for dark current cancellation for an optical transceiver in accordance with another embodiment of the present disclosure.

FIG. 6 is a cross-sectional view of an IC chip for dark current cancellation for an optical transceiver in accordance with an embodiment of the present disclosure.

FIG. 7 is a top view of the IC chip of FIG. 6.

FIG. 8 is a flowchart of a process of manufacturing an IC chip for dark current cancellation for an optical transceiver in accordance with an embodiment of the present disclosure.

### DETAILED DESCRIPTION OF THE PREFERRED EMBODIMENTS

### Overview

The present disclosure provides techniques, systems, devices and methods to enhance received optical power monitoring accuracy in optical transceivers. The techniques, systems, devices and methods of the present disclosure use a reference dark current to calibrate the optical current produced by a photodetector in an optical transceiver. The reference dark current may be obtained by estimation from calculation, a lookup table, or from a dummy photodetector. The proposed techniques, systems, devices and methods can enhance the accuracy of the received signal strength indication (RSSI) function for optical transceivers, especially for those having a photodetector with large dark current.

Moreover, the techniques, systems, devices and methods of the present disclosure may utilized a receiver optical sub-assembly (ROSA) package scheme, e.g., a 5-pin or 6-pin ROSA, to provide a reference dark current for system optical power calibration. An additional dummy photodetector, independent or integrated with a main photodetector of the optical transceiver, may be used to provide a reference dark current. A 5-pin or 6-pin transistor outline (TO)-header may be used in the ROSA package. Dark current of the dummy photodetector may be monitored through one lead of the 5-pin or 6-pin ROSA.

Furthermore, the present disclosure provides a new APD structure, which includes a normal APD and a dummy APD for compensating dark current.

### Example Implementations

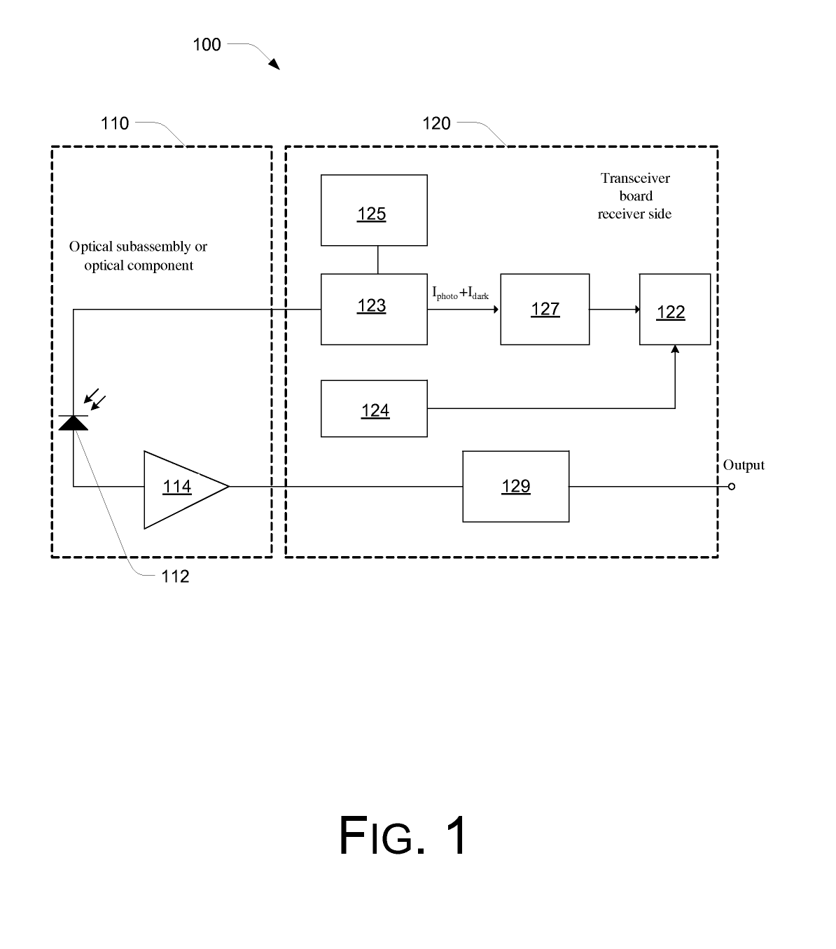

FIG. 1 illustrates a device 100 for dark current cancellation for an optical transceiver in accordance with an embodiment of the present disclosure. Device 100 may be a part of an optical transceiver. The transceiver may include, for example, GBIC, SFP, SFP+, XFP, Xenpak, XPAK, XAUI, QSFP+, CX4, transponder or X2 modules, but is not limited thereto.

In the example shown in FIG. 1, device 100 includes a photosensitive module 110 and a processing module 120 that is coupled to the photosensitive module 110. Photosensitive module 110 may be, for example, an optical sub-assembly or an optical component. The sub-assembly may be, for example, a receiver optical sub-assembly (ROSA) or a bidirectional optical sub-assembly (BOSA). Processing module 120 may be a part of the optical transceiver on the receiver side of the optical transceiver.

Photosensitive module 110 is configured to detect an optical signal, e.g., an optical signal received from an optical fiber. Photosensitive module 110 is also configured to generate a first signal, e.g., a total current, responsive to detecting the optical signal. Processing module 120 is configured to determine a value of a second signal, e.g., a reference dark current, that is related to noise, e.g., dark current. Processing module 120 is also configured to determine a value of a third signal, e.g., a signal current or photon current, which is related to a difference between a value of the first signal and the value of the second signal. The first signal may be a total current, the second signal may be a reference dark current, and the third signal may be a signal current. More specifically, processing module 120 can cancel the effect of dark current on optical power monitoring by subtracting the value of the dark current from the value of the total current, the processing module 120 can calculate the value of the signal current, which may be proportional to the optical signal received from the optical fiber that carries digital data.

In one embodiment, as shown in FIG. 1, photosensitive module 110 includes at least a main photodetector 112.

In one embodiment, main photodetector 112 is a photodiode or an APD.

Optionally, as shown in FIG. 1, photosensitive module 110 also includes a TIA 114 coupled to the main photodetector 112.

In one embodiment, as shown in FIG. 1, processing module 120 includes a temperature sensor 124 and a control unit 122. Control unit 122 may be, for example, a microcontroller unit or a digital signal processing unit. Temperature sensor 124 is configured to detect an ambient temperature around photosensitive module 110 and generate a temperature signal responsive to detecting the ambient temperature. Control unit 122 is coupled to receive the temperature signal and the first signal. Control unit 122 is configured to determine the value of the third signal based at least in part on the temperature signal.

Control unit 122 can determine the value of the third signal at different temperatures in one of several ways, and two examples are described herein.

In one embodiment, control unit 122 determines the value of the third signal by first determining the value of the second signal corresponding to a temperature associated with the temperature signal using a lookup table, which may be stored in control unit 122 or a memory (not shown). The lookup table contains pre-measured dark current values of photodetector 112. Control unit 122 then subtracts the value of the second signal from the value of the first signal, cancelling the effect of dark current, to obtain the value of the third signal, e.g., the signal current.

Alternatively, control unit 122 determines the value of the third signal by first calculating the value of the second signal corresponding to a temperature associated with the temperature signal using temperature coefficients associated with the photosensitive module. Such temperature coefficients may be stored in control unit 122 or a memory (not shown). Control unit 122 then subtracts the value of the second signal from the value of the first signal.

In the example shown in FIG. 1, processing module 120 further includes a current mirror 123, a photodiode bias controller 125, a signal transformer and analog-to-digital converter 127, and a limiting amplifier 129 that are coupled to one another as shown in FIG. 1. As the structure and functionality of these components are well known in the art, in the interest of brevity a detailed description thereof is not provided herein.

A system optical power calibration method according to one embodiment is described below.

Before assembling photodetector 112 into photosensitive module 110, the dark current of photodetector 112 is measured under different temperatures, e.g., over a range of −40° C. to 85° C. Then, those measured dark current values are stored in the lookup table in control unit 122 or a memory external to control unit 122. Furthermore, temperature coefficients of dark current can be obtained from data fitting and stored in control unit 122 or a memory external to control unit 122. When the system, e.g., optical transceiver in which device 100 is contained, is operated under different conditions and temperatures, control unit 122 calibrates photon current from photodetector 112 using a value of dark current corresponding to the measured ambient temperature at the time either from the lookup table or from temperature coefficient calculations.

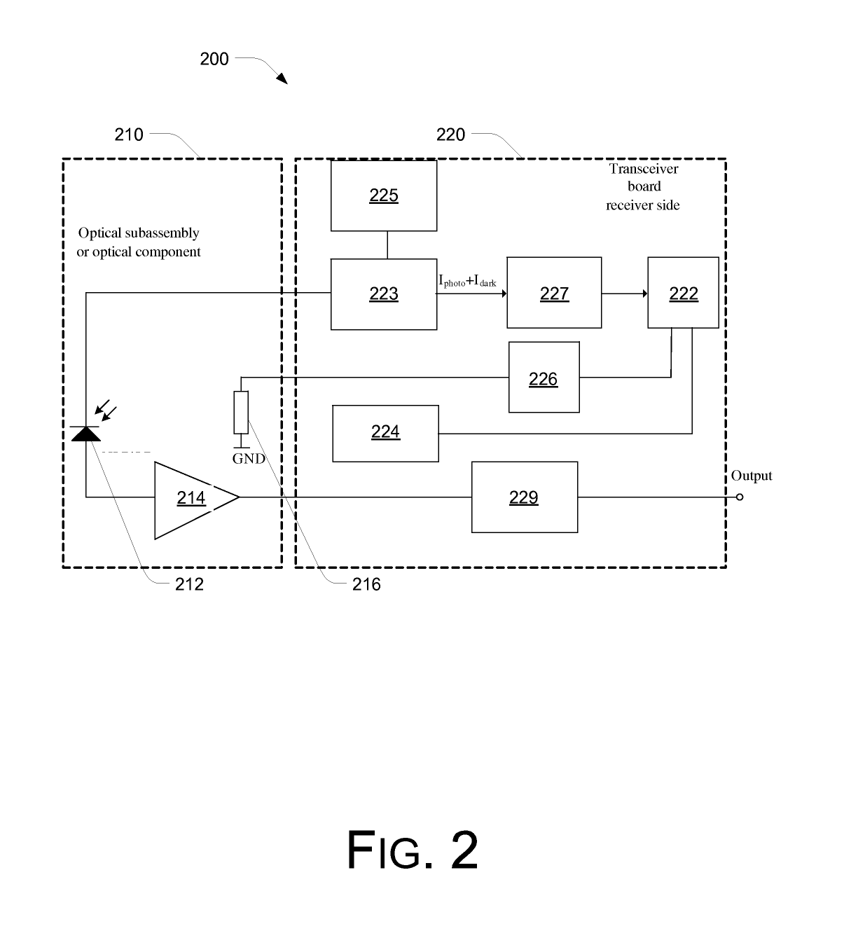

FIG. 2 illustrates a device 200 for dark current cancellation for an optical transceiver in accordance with another embodiment of the present disclosure.

In the example shown in FIG. 2, device 200 includes a photosensitive module 210 and a processing module 220 coupled to the photosensitive module. As shown in FIG. 2, photosensitive module 210 includes at least a main photodetector 212. In one embodiment, main photodetector 212 is a photodiode or an APD. Optionally, as shown in FIG. 2, photosensitive module 210 also includes a TIA 214 coupled to the main photodetector 212. Processing module 220 includes a temperature sensor 224 and a control unit 222. Processing module 220 further includes a current mirror 223, a photodiode bias controller 225, a signal transformer and analog-to-digital converter 227, and a limiting amplifier 229 that are coupled to one another as shown in FIG. 2. As the structure and functionality of these components of device 200 are similar or identical to those of device 100, in the interest of brevity a detailed description thereof is not provided herein.

Device 200 differs from device 100 in that photosensitive module 210 of device 200 further includes a heating element 216, and that processing unit 220 of device 200 further includes a power supply 226. Heating element 216 is configured to generate heat when switched on by control unit 222 through power supply 226 responsive to the ambient temperature measured by temperature sensor 224 being less than a threshold temperature. Heating element 216 may be, for example, a resistive heater (e.g., resistor), capacitive heater or inductive heater, but is not limited thereto.

As the voltage provided to heating element 216 is controlled by control unit 222, control unit 222 enables heating function only when the ambient temperature drops to some set value, e.g., 0° C. Because heating element 216 can adjust the temperature inside photosensitive module 210, the photodetector 212 can operate at an optimized temperature to allow photodetector 212 to reach its optimal performance.

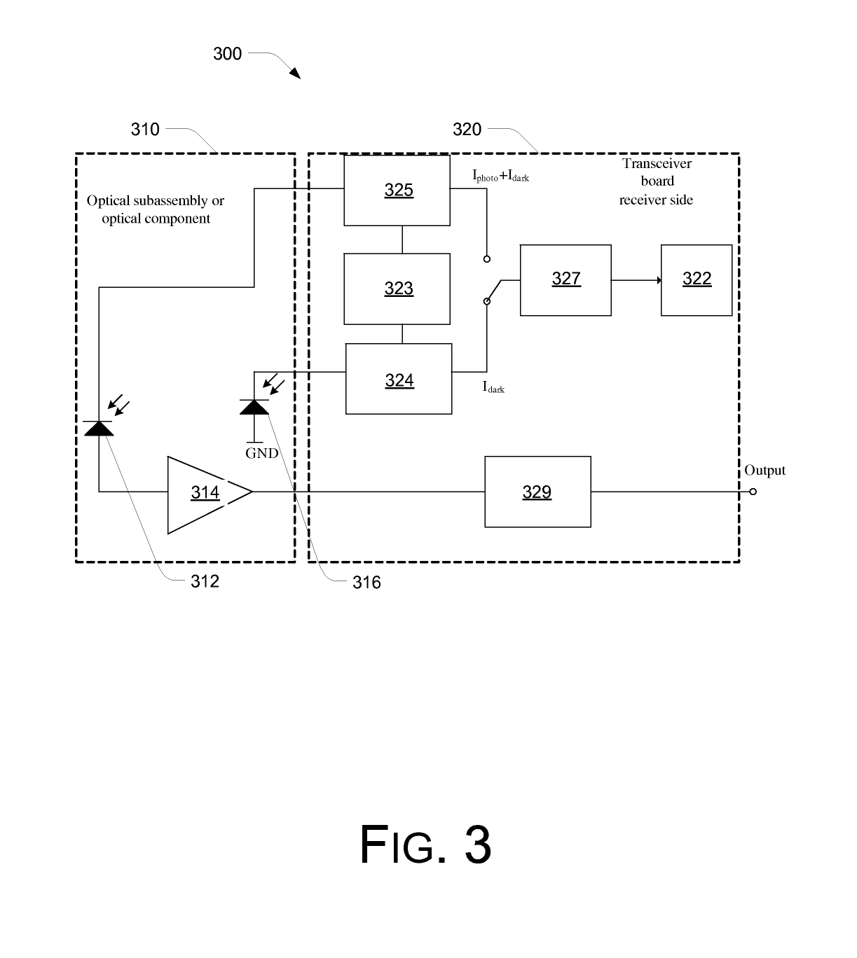

FIG. 3 illustrates a device 300 for dark current cancellation for an optical transceiver in accordance with yet another embodiment of the present disclosure.

In the example shown in FIG. 3, device 300 includes a photosensitive module 310 and a processing module 320 coupled to the photosensitive module. As shown in FIG. 3, photosensitive module 310 includes at least a main photodetector 312 and a dummy photodetector 316. Main photodetector 312 is configured to detect the optical signal and generate a total current as the first signal responsive to detecting the optical signal. Dummy photodetector 316 is configured to detect noise and generate a reference dark current as the second signal responsive to detecting the noise. In one embodiment, main photodetector 312 is a photodiode or an APD. Optionally, as shown in FIG. 3, photosensitive module 310 also includes a TIA 314 coupled to the main photodetector 312.

As shown in FIG. 3, processing module 320 includes a control unit 322, a photodiode bias controller 323, a first current mirror 325, a second current mirror 324, a signal transformer and analog-to-digital converter 327, and a limiting amplifier 329 that are coupled to one another as shown in FIG. 3. More specifically, the first current mirror 325 is coupled to receive the first signal from main photodetector 312, and the first current mirror is configured to mirror the first signal. The second current mirror 324 is coupled to receive the second signal from dummy photodetector 316, and the second current mirror 324 is configured to mirror the second signal. A switch is provided to allow control unit 322 to receive the first signal from photodetector 312 via the first current mirror 325 and signal transformer and analog-to-digital converter 327, or to receive the second signal from dummy photodetector 316 via the second current mirror 324 and signal transformer and analog-to-digital converter 327. Control unit 322 is configured to determine the value of the third signal by subtracting the value of the second signal from the value of the first signal.

In one embodiment, dummy photodetector 316 is a discrete photodetector separate from main photodetector 312, and one or more physical characteristics of dummy photodetector 316 (e.g., electrical, optical, thermal, etc.) are substantially identical to corresponding one or more physical characteristics of main photodetector 312.

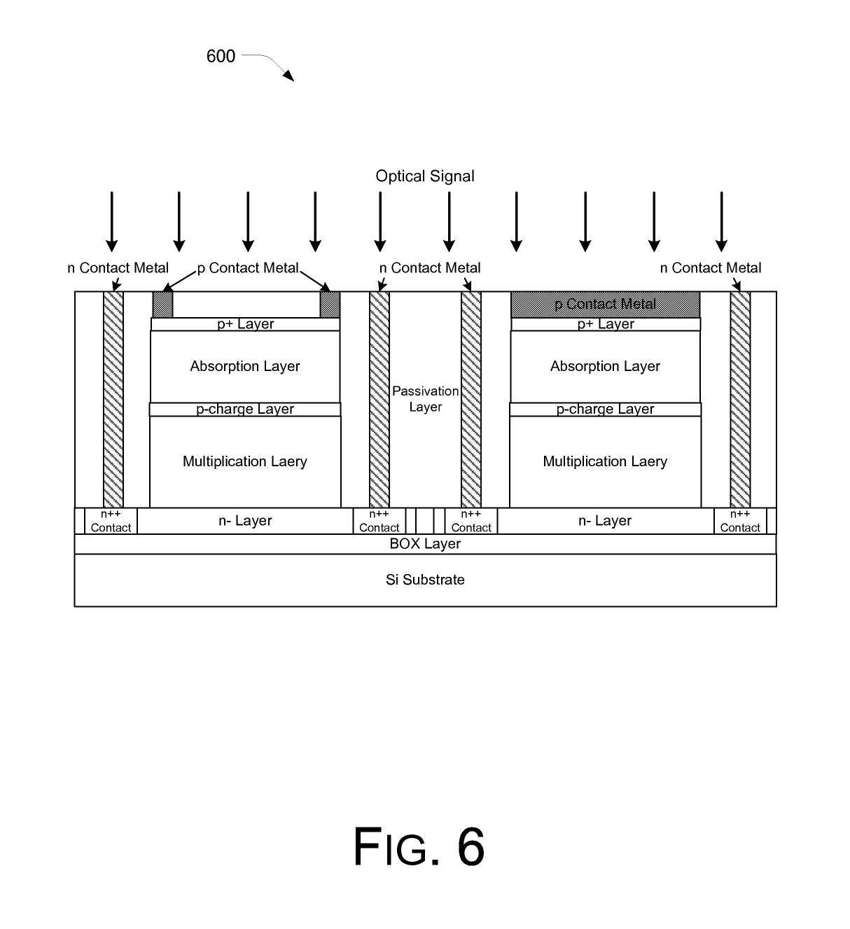

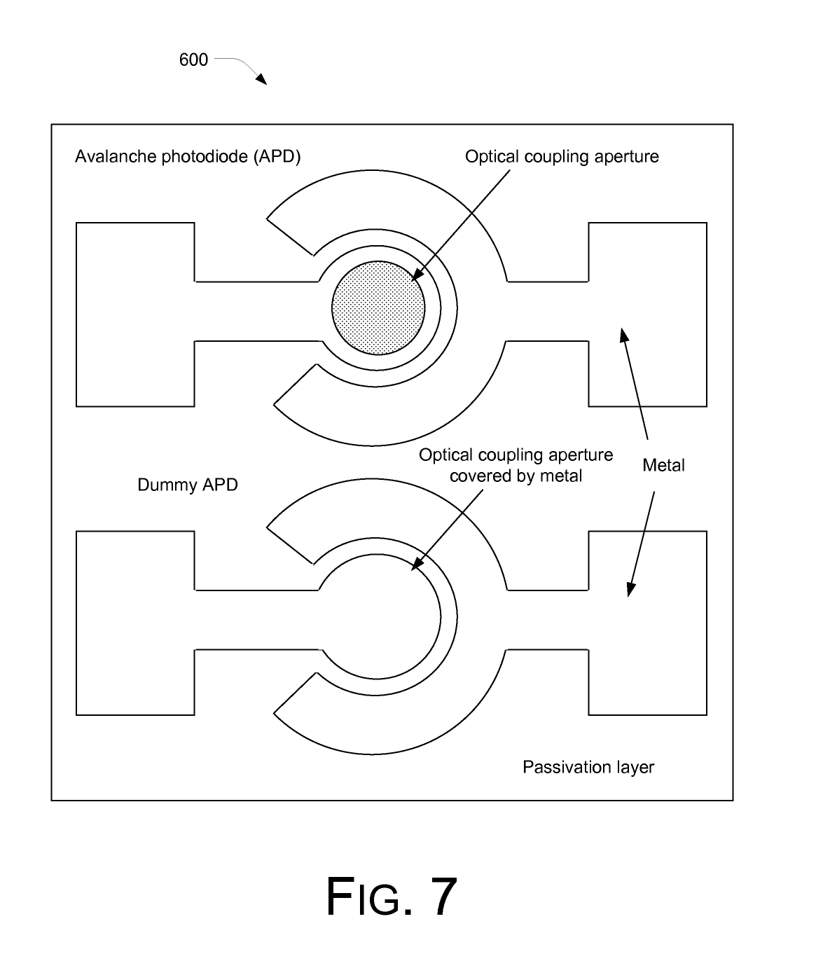

Alternatively, dummy photodetector 316 and main photodetector 312 are integral parts of an IC chip. Detailed description of the structure of such IC chip will be provided later with reference to FIGS. 6 and 7.

As mentioned earlier, during transceiver operation, it is necessary to monitor optical power received by one or more photodetectors of the transceiver for network administration and/or for adaptively adjusting the optical output power at the transmitter portion. However, dark current of the photodetector(s) can reduce the accuracy of optical power monitoring, especially when dark current is large or is close to photocurrent typically during high temperature operations. This problem limits the development of long-haul high-speed optical communication systems.

To address the aforementioned problem, the present disclosure proposes modifying the structure of a conventional ROSA by using a 6-pin TO header in ROSA packaging. The 6-pin ROSA can provide a reference dark current for an optical transceiver associated with device 100, device 200, device 300 and any variations thereof.

Table 1 below indicates an example assignment of the six pins of the 6-pin ROSA.

TABLE 1
Pin assignment of 6-pin ROSA

| Pin number | Name | Function |
|---|---|---|
| 1 | Out+ | Signal output positive |
| 2 | Vcc | TIA bias |
| 3 | Vpd | Photodetector bias |
| 4 | ID | Reference dark |
| | | current |
| 5 | Out− | Signal output negative |
| 6 | GND | Ground |

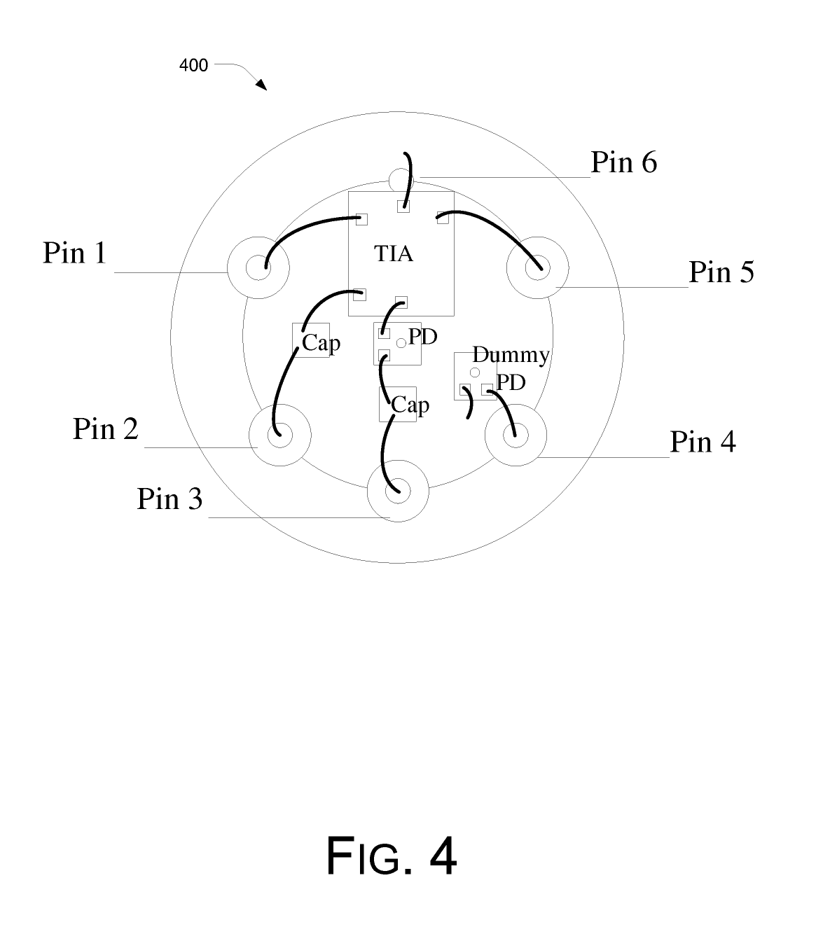

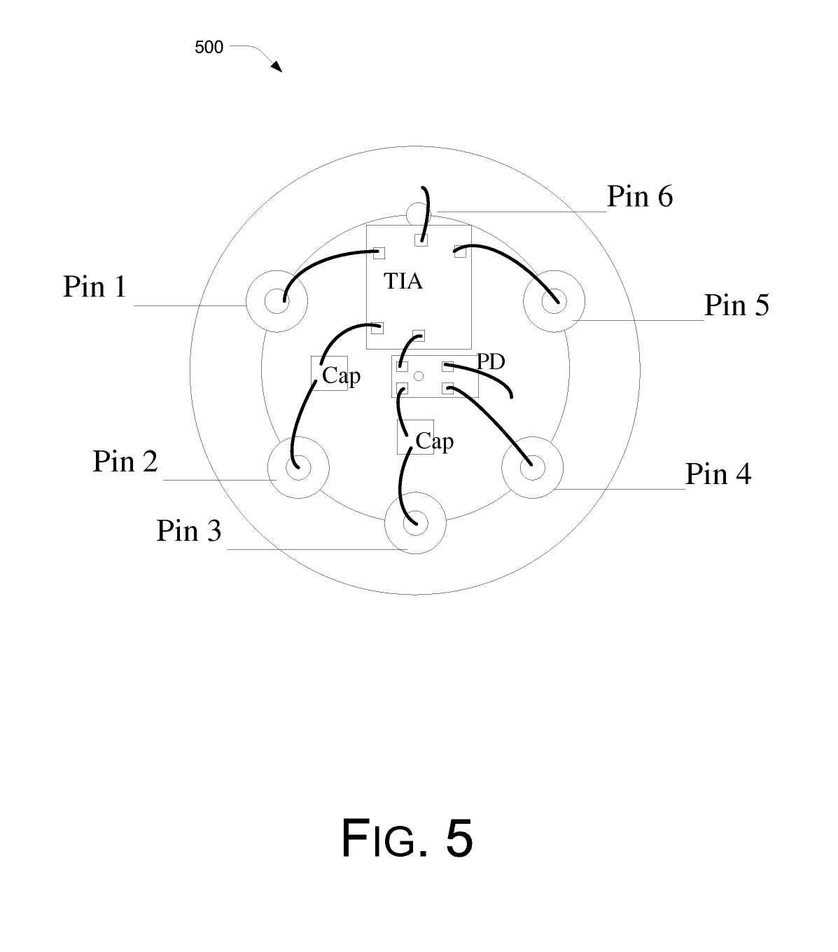

There are two approaches to realizing the dark current monitor function in the 6-pin-ROSA, one is shown in FIG. 4 and the other is shown in FIG. 5.

FIG. 4 illustrates a top view of 6-pin ROSA 400 for dark current cancellation for an optical transceiver in accordance with an embodiment of the present disclosure.

FIG. 4 shows the die attaching and wire bond connections of the 6-pin ROSA 400 for dark current monitoring with a separate dummy photodetector. As shown in FIG. 4, the 6-pin ROSA 400 includes a normal photodetector, a separated dummy photodetector, a trans-impedance amplifier and two single-layer ceramic capacitors. The normal photodetector, which has bias voltage applied via pin 3, converts an input optical signal into an electrical signal. Trans-impedance amplifier amplifies the electrical signal from the normal photodetector. The dummy photodetector is attached near the normal photodetector so as to ensure the normal photodetector and the dummy photodetector are operating under the same temperature. The bias voltage of the dummy photodetector is applied via pin 4.

Thus, in the 6-pin ROSA 400, the normal photodetector (e.g., a photodiode or APD) is used to receive optical power. The dummy photodetector (e.g., a photodiode or APD) is attached near the normal photodetector. P pad and N pads of the dummy photodetector are connected to ground (GND) and pin 4, respectively. The dummy photodetector has almost the same conditions as the normal photodetector, including dark current, temperature coefficient, bias, temperature, etc. The only one difference is that the dummy photodetector is without input optical power.

During the operation of the 6-pin ROSA 400, voltage is imposed on pin 3 for the normal photodetector and on pin 4 for the dummy photodetector. The dark current of the normal photodetector can be monitored by measuring the current flowing through pin 4. The voltage applied on pin 4 is a little less than the voltage applied on pin 3 due to the positive potential at TIA input port.

FIG. 5 illustrates a top view of a 6-pin ROSA 500 for dark current cancellation for an optical transceiver in accordance with another embodiment of the present disclosure.

As shown in FIG. 5, a dummy photodetector is integrated with a normal photodetector (e.g., a photodiode or APD) in one chip. The dummy photodetector has almost the same conditions as the normal photodetector, including dark current, temperature coefficient, bias, atmosphere temperature, etc. The only one difference is that the dummy photodetector is without input optical power.

P pad and N pads of the dummy photodetector are connected to ground (GND) and pin 4, respectively.

During the operation of the 6-pin ROSA 500, voltage is imposed on pin 3 for the normal photodetector and on pin 4 for the dummy photodetector. The dark current of the normal photodetector can be monitored by measuring the current flowing through pin 4. The voltage applied on pin 4 is a little less than the voltage applied on pin 3 due to the positive potential at TIA input port.

As shown in FIG. 5, the 6-pin ROSA 500 includes a chip in which the normal photodetector and the dummy photodetector are integrated. The 6-pin ROSA 500 also includes a trans-impedance amplifier and two single-layer ceramic capacitors. The normal photodetector, which has bias voltage applied via pin 3, converts an input optical signal into an electrical signal. Trans-impedance amplifier amplifies the electrical signal from the normal photodetector. The bias voltage of the dummy photodetector is applied via pin 4.

FIG. 6 illustrates a cross-sectional view of an IC chip 600 for dark current cancellation for an optical transceiver in accordance with an embodiment of the present disclosure. FIG. 7 illustrates a top view of the IC chip 600 of FIG. 6.

In the example shown in FIGS. 6 and 7, IC chip 600 includes: a substrate; an electrically insulating layer on the substrate; a first semiconductor structure on the electrically insulating layer as the main photodetector; a second semiconductor structure on the electrically insulating layer as the dummy photodetector; a passivation layer on the electrically insulating layer such that the main photodetector and the dummy photodetector are physically and electrically isolated from one another by the passivation layer at least in a direction substantially parallel to a surface of the electrically insulating layer; and an optical barricade layer at least partially surrounding the dummy photodetector such that an optical coupling region of the dummy photodetector is covered by the optical barricade layer to avoid the dummy photodetector receiving the optical signal.

In one embodiment, the electrically insulating layer may be a BOX layer, the substrate may be a silicon substrate, and the silicon substrate and the BOX layer may be at least a part of a silicon-on-insulator wafer.

In one embodiment, the optical barricade layer may include a metallic material.

In one embodiment, the photosensitive module may include a ROSA, and the photosensitive module may further include a TIA coupled to the main photodetector.

The use of the substrate and bottom isolation layer, such as Si substrate and BOX layer of a SOI wafer, make possible the isolation of a normal photodetector and a dummy photodetector in the same IC chip. Passivation layer, made of SiO2 material for example, provides the isolation of the normal photodetector and the dummy photodetector in horizontal directions (i.e., directions across and parallel to the top surface of the substrate or BOX layer as shown in FIG. 6).

The optical barricade layer, made of metal material for example, covers the entire optical coupling region of the dummy photodetector to avoid the dummy photodetector receiving optical signal during operation.

As shown in FIG. 7, the structure of the IC chip has a number of feature in horizontal directions. Two semiconductor structures, one as the normal photodetector and the other as the dummy photodetector, are on the same chip, and are isolated from other chip by scrub line. The normal photodetector, which may be an APD, and the dummy photodetector as well as their contact pads are isolated by the passivation layer. The passivation layer is used to avoid cross talk between two devices during high-speed operation.

The angle between two pads, in each of the normal photodetector and the dummy photodetector, is 180° apart from one another, which can be modified depending on needs of the actual implementation.

### Example Processes

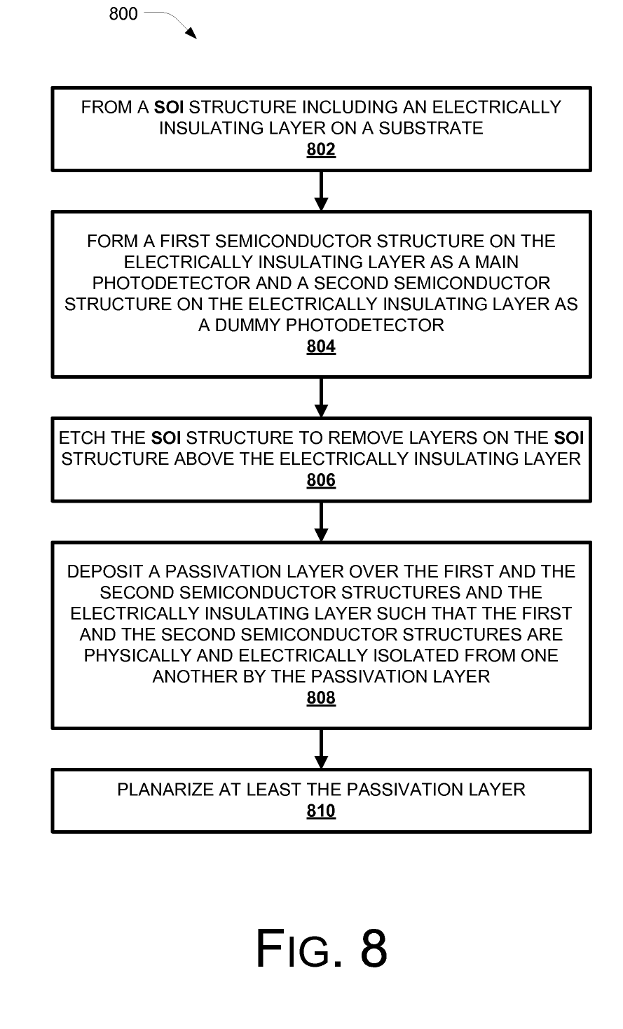

FIG. 8 illustrates a process 800 of manufacturing the IC chip 600 of FIGS. 6 and 7 in accordance with an embodiment of the present disclosure.

Process 800 includes one or more operations, actions, or functions as illustrated by one or more of blocks 802, 804, 806, 808, and 810. Although illustrated as discrete blocks, various blocks may be divided into additional blocks, combined into fewer blocks, or eliminated, depending on the desired implementation.

At 802, process 800 forms a SOI structure including an electrically insulating layer on a substrate.

At 804, process 800 forms a first semiconductor structure on the electrically insulating layer, as a main photodetector, and a second semiconductor structure on the electrically insulating layer, as a dummy photodetector, e.g., formed simultaneously.

At 806, process 800 performs an etching process to etch the SOI structure to remove layers of the SOI structure above the electrically insulating layer.

At 808, process 800 deposits a passivation layer over the first semiconductor structure, the second semiconductor structure, and the electrically insulating layer such that the first semiconductor structure and the second semiconductor structure are physically and electrically isolated from one another by the passivation layer at least in a direction substantially parallel to a surface of the electrically insulating layer.

At 810, process 800 performs a planarization process to planarize at least the passivation layer.

In one embodiment, the electrically insulating layer may be a BOX layer, and the substrate may be a silicon substrate.

In one embodiment, the optical barricade layer may include a metallic material.

In one embodiment, the method may further include forming an optical barricade layer that at least partially surrounds the second semiconductor structure such that an optical coupling region of the second semiconductor structure is covered by the optical barricade layer to avoid the second semiconductor structure receiving the optical signal.

### Additional Note

Although some embodiments are disclosed above, they are not intended to limit the scope of the present disclosure. It will be apparent to those skilled in the art that various modifications and variations can be made to the disclosed embodiments of the present disclosure without departing from the scope or spirit of the present disclosure. In view of the foregoing, the scope of the present disclosure shall be defined by the following claims and their equivalents.

What is claimed is:

1. A device, comprising:
a photosensitive module, the photosensitive module configured to detect an optical signal and generate a first signal responsive to detecting the optical signal; and
a processing module coupled to the photosensitive module, the processing module configured to determine a value of a second signal that is related to noise and determine a value of a third signal that is related to a difference between a value of the first signal and the value of the second signal.

2. The device of claim 1, wherein the photosensitive module comprises at least a main photodetector.

3. The device of claim 2, wherein the first signal comprises a total current, wherein the second signal comprises a reference dark current, and wherein the third signal comprises a signal current.

4. The device of claim 2, wherein the photosensitive module further comprises:
a trans-impedance amplifier (TIA) coupled to the main photodetector.

5. The device of claim 1, wherein the processing module comprises:
a temperature sensor configured to detect an ambient temperature around the photosensitive module and generate a temperature signal responsive to detecting the ambient temperature; and
a control unit coupled to receive the temperature signal and the first signal, the control unit configured to determine the value of the third signal based at least in part on the temperature signal.

6. The device of claim 5, wherein the control unit determines the value of the third signal by:
determining the value of the second signal corresponding to a temperature associated with the temperature signal using a lookup table; and
subtracting the value of the second signal from the value of the first signal.

7. The device of claim 5, wherein the control unit determines the value of the third signal by:
calculating the value of the second signal corresponding to a temperature associated with the temperature signal using temperature coefficients associated with the photosensitive module; and
subtracting the value of the second signal from the value of the first signal.

8. The device of claim 5, wherein the photosensitive module further comprises:
a heating element, the heating element configured to generate heat when switched on by the control unit responsive to the ambient temperature being less than a threshold temperature.

9. The device of claim 2, wherein the photosensitive module further comprises:
a dummy photodetector, the dummy photodetector configured to detect the noise and generate the second signal responsive to detecting the noise.

10. The device of claim 9, wherein the dummy photodetector comprises a discrete photodetector separate from the main photodetector, and wherein one or more physical characteristics of the dummy photodetector are substantially identical to corresponding one or more physical characteristics of the main photodetector.

11. The device of claim 9, wherein the dummy photodetector and the main photodetector are integral parts of an integrated circuit (IC) chip.

12. The device of claim 11, wherein the main photodetector comprises an avalanche photodiode, and wherein the IC chip comprises:
a substrate;
an electrically insulating layer on the substrate;
a first semiconductor structure on the electrically insulating layer as the main photodetector;
a second semiconductor structure on the electrically insulating layer as the dummy photodetector;
a passivation layer on the electrically insulating layer such that the main photodetector and the dummy photodetector are physically and electrically isolated from one another by the passivation layer at least in a direction substantially parallel to a surface of the electrically insulating layer; and
an optical barricade layer at least partially surrounding the dummy photodetector such that an optical coupling region of the dummy photodetector is covered by the optical barricade layer to avoid the dummy photodetector receiving the optical signal.

13. The device of claim 12, wherein the electrically insulating layer comprises a buried oxide (BOX) layer, wherein the substrate comprises a silicon substrate, and wherein the silicon substrate and the BOX layer comprise at least a part of a silicon-on-insulator wafer.

14. The device of claim 12, wherein the optical barricade layer comprises a metallic material.

15. The device of claim 9, wherein the photosensitive module further comprises:
a trans-impedance amplifier (TIA) coupled to the main photodetector.

16. The device of claim 9, wherein the processing module comprises:
a first current mirror coupled to receive the first signal from the main photodetector, the first current mirror configured to mirror the first signal;
a second current mirror coupled to receive the second signal from the dummy photodetector, the second current mirror configured to mirror the second signal; and
a control unit coupled to receive the mirrored first signal and the mirrored second signal from the first and the second current mirrors, the control unit configured to determine the value of the third signal by subtracting the value of the second signal from the value of the first signal.

17. The device of claim 1, wherein the photosensitive module comprises:
a main photodetector, the main photodetector configured to detect the optical signal and generate a total current as the first signal responsive to detecting the optical signal; and
a dummy photodetector, the dummy photodetector configured to detect the noise and generate a reference dark current as the second signal responsive to detecting the noise.

18. The device of claim 17, wherein the dummy photodetector comprises a discrete photodetector separate from the main photodetector, and wherein one or more physical characteristics of the dummy photodetector are substantially identical to corresponding one or more physical characteristics of the main photodetector.

19. The device of claim 17, wherein the dummy photodetector and the main photodetector are integral parts of an integrated circuit (IC) chip.

20. The device of claim 19, wherein the main photodetector comprises an avalanche photodiode, and wherein the IC chip comprises:
a substrate;
an electrically insulating layer on the substrate;
a first semiconductor structure on the electrically insulating layer as the main photodetector;
a second semiconductor structure on the electrically insulating layer as the dummy photodetector;
a passivation layer on the electrically insulating layer such that the main photodetector and the dummy photodetector are physically and electrically isolated from one another by the passivation layer at least in a direction substantially parallel to a surface of the electrically insulating layer; and
an optical barricade layer at least partially surrounding the dummy photodetector such that an optical coupling region of the dummy photodetector is covered by the optical barricade layer to avoid the dummy photodetector receiving the optical signal.

21. The device of claim 20, wherein the electrically insulating layer comprises a buried oxide (BOX) layer, wherein the substrate comprises a silicon substrate, and wherein the silicon substrate and the BOX layer comprise at least a part of a silicon-on-insulator wafer.

22. The device of claim 20, wherein the optical barricade layer comprises a metallic material.

23. The device of claim 17, wherein the photosensitive module comprises a receiver optical sub-assembly (ROSA), and the photosensitive module further comprises:
a trans-impedance amplifier (TIA) coupled to the main photodetector.

24. The device of claim 17, wherein the processing module comprises:
a first current mirror coupled to receive the first signal from the main photodetector, the first current mirror configured to mirror the first signal;
a second current mirror coupled to receive the second signal from the dummy photodetector, the second current mirror configured to mirror the second signal; and
a control unit coupled to receive the mirrored first signal and the mirrored second signal from the first and the second current mirrors, the control unit configured to determine the value of the third signal by subtracting the value of the second signal from the value of the first signal.

25. A method of manufacturing an integrated circuit (IC) chip for dark current cancellation for an optical transceiver, comprising:
forming a silicon-on-insulator (SOI) structure including an electrically insulating layer on a substrate;
forming a first semiconductor structure on the electrically insulating layer, as a main photodetector, and a second semiconductor structure on the electrically insulating layer, as a dummy photodetector;
etching the SOI structure to remove layers of the SOI structure above the electrically insulating layer;
depositing a passivation layer over the first semiconductor structure, the second semiconductor structure, and the electrically insulating layer such that the first semiconductor structure and the second semiconductor structure are physically and electrically isolated from one another by the passivation layer; and
planarizing at least the passivation layer.

26. The method of claim 25, wherein the electrically insulating layer comprises a buried oxide (BOX) layer, and wherein the substrate comprises a silicon substrate.

27. The method of claim 25, wherein the optical barricade layer comprises a metallic material.

28. The method of claim 25, further comprising:
forming an optical barricade layer that at least partially surrounds the second semiconductor structure such that an optical coupling region of the second semiconductor structure is covered by the optical barricade layer to avoid the second semiconductor structure receiving the optical signal.
